(19) United States
(12) Patent Application Publication
(10) Pub. No.: US 2025/0308897 A1
(43) Pub. Date: Oct. 2, 2025

(54) HARD MASK PROTECTION OF METAL INTERCONNECTS

(71) Applicant: Tokyo Electron Limited, Tokyo (JP)

(72) Inventors: Sophia Rogalskyj, Albany, NY (US); Nicholas Joy, Albany, NY (US); Joshua Baillargeon, Albany, NY (US); Nargess Arabchigavkani, Slingerlands, NY (US)

(21) Appl. No.: 18/620,417

(22) Filed: Mar. 28, 2024

(51) Int. Cl. H01L 21/033; H01L 21/02; H01L 21/311; H01L 21/3205; H01L 21/3213; H01L 21/768

(52) U.S. Cl. CPC H01L 21/0337; H01L 21/02244; H01L 21/0226; H01L 21/0332; H01L 21/31116; H01L 21/32051; H01L 21/32136; H01L 21/32139; H01L 21/76802; H01L 21/7682; H01L 21/76834; H01L 21/76877

(57) ABSTRACT

A method for protecting metal interconnects includes depositing a first layer having a first electrochemical potential over a substrate, depositing a second layer having a second electrochemical potential over the first layer, where the second electrochemical potential is less than the first electrochemical potential. The method includes creating an opening through the second layer, and extending the opening through the first layer by etching the first layer and the second layer, where at least some of the second layer is deposited over the first layer on sidewalls of the opening.

### TECHNICAL FIELD

The present disclosure relates generally to semiconductor fabrication, and, in particular implementations, to hard mask protection of metal interconnects.

### BACKGROUND

Generally, a semiconductor integrated circuit (IC) is fabricated by sequentially depositing conductive, dielectric, and semiconductor layers over a semiconductor substrate to form IC devices. Semiconductor processing includes patterning layers using photolithography and etch to form electronic and interconnect elements like transistors, resistors, capacitors, metal lines, contacts, and vias in one monolithic structure. At each new technology node, feature sizes are reduced, resulting in increased packing density of IC elements to reduce cost.

As new generations of circuit designs are developed, various different optimizations are considered, including different material compositions. In the case of metal lines for interconnects, a variety of different metals and metal combinations can potentially be used that may have varying properties, such as different electrochemical potentials than prior used metals or other metals used. The electrochemical potentials of different metals and metal combinations used in semiconductor interconnects may result in new challenges for preventing deterioration of the materials used, such as by oxidation/reduction reactions.

### SUMMARY

In one aspect, a first method is disclosed. The first method can include depositing a first layer having a first electrochemical potential over a substrate, and depositing a second layer having a second electrochemical potential over the first layer, where the second electrochemical potential is less than the first electrochemical potential. The first method can also include creating an opening through the second layer, and extending the opening through the first layer by etching the first layer and the second layer, where at least some of the second layer is deposited over the first layer on sidewalls of the opening during the extending.

In another aspect, a first process is disclosed. The first process can include depositing a first metal over a semiconductor substrate comprising silicon, the first metal having a first electrochemical potential and forming a first layer, depositing a second metal over the first layer, the second metal having a second electrochemical potential less than the first electrochemical potential and forming a second layer, and patterning the second layer to form a hard mask having an opening through the hard mask. The first process can also include etching the hard mask to extend the opening through the first layer, and, during the etching, sputtering the second metal over the first metal at sidewalls of the opening.

In a further aspect, a second process is disclosed. The second process can include providing a plurality of layers, at least some of the layers comprising a metal mask layer, a first metal layer under the metal mask layer, and a silicon-containing layer under the first metal layer, defining an opening in the metal mask layer, and etching the metal mask layer through the opening to define sidewalls of the metal mask layer and of the first metal layer. During the etching, the second process can include causing a second metal from the metal mask layer to be sputtered on the sidewalls over the first metal layer, the metal mask layer having a second electrochemical potential that is less than a first electrochemical potential of the first metal layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a depiction of patterned metal interconnects, in one implementation;

FIG. 2 is a flowchart depicting a method for hard mask protection of metal interconnects, in one implementation;

FIG. 3 is a depiction of a plasma processing system, in one implementation;

FIGS. 4A, 4B, 4C, 4D, 4E, 4F, 4G, 4H, 4I, and 4J are depictions of a process for semiconductor fabrication, in one implementation;

FIG. 5 is a flowchart depicting a method for protecting metal interconnects, in an implementation;

FIG. 6 is a flowchart depicting a process for protecting metal interconnects, in an implementation;

FIG. 7 is a flowchart depicting a process for protecting metal interconnects, in an implementation; and

FIG. 8 is a depiction of sidewall sputtering over an interconnect metal, in one implementation.

### DETAILED DESCRIPTION

This disclosure describes hard mask protection of metal interconnects, such as by using a metal mask layer during etching of a metal interconnect, in various implementations.

In the following description, details are set forth by way of example to facilitate discussion of the disclosed subject matter. It will be apparent to a person of ordinary skill in the field, however, that the disclosed implementations are exemplary and not exhaustive of all possible implementations.

Throughout this disclosure, a hyphenated form of a reference numeral refers to a specific instance of an element and the un-hyphenated form of the reference numeral refers to the element generically or collectively. Thus, as an example (not shown in the drawings), device “12-1” refers to an instance of a device class, which may be referred to collectively as devices “12” and any one of which may be referred to generically as a device “12”. In the figures and the description, like numerals are intended to represent like elements.

As noted, in metal lines for interconnects, a variety of different metals and metal combinations are in consideration for next generation IC designs. Such metal interconnects may be formed in back end of line (BEOL) processing, after semiconductor devices have been formed in the front end of line (FEOL). BEOL processing involves laying down multiple layers of dielectric insulators and metal conductors to form metal interconnects in three dimensions (3D) that connect the semiconductor devices formed in FEOL processing.

In many conventional designs, conductive interconnects are made primarily with copper (Cu). Copper was introduced around 1997 and replaced aluminum (Al) because of copper's lower resistance increased performance. Copper interconnects provided the ability to further reduce critical dimensions (CD) and power consumption, among other benefits. Since copper (and also titanium (Ti)) cannot be patterned using typical lithography techniques involving photoresist masking followed by plasma etching, an additive patterning was used. Such additive patterning of copper interconnects in BEOL is referred to as a damascene or dual-damascene process, in which trenches and/or vias are overfilled with copper using an electroplating process, and then chemical mechanical polishing (CMP) (or another wet polishing technique) is used to remove the excess material and form the final interconnect shape.

Furthermore, since copper can easily diffuse into the surrounding materials used in BEOL processes, a barrier layer is used with copper interconnects that completely surrounds and isolates the copper to prevent diffusion into adjacent materials, which would otherwise result in deleterious contamination and in early failure of the IC. The barrier layer should also have sufficient conductivity to facilitate good electrical contact. Commonly used barrier layers include titanium nitride (TiN) and tantalum nitride (TaN) to surround the copper interconnects, among others. However, as CD for the interconnects are scaled down into the nanometer range, such barrier layers used with copper interconnects can become increasingly problematic and can represent a fundamental constraint on the continued use of copper in BEOL interconnects. Specifically, a minimum thickness of the barrier layer is used to provide a sufficient diffusion barrier. Thus, as interconnect CD is reduced further and further, such as down to 10 nm and smaller, the minimum thickness of the barrier layer used with copper results in an increasing fraction of the total conductor volume of the interconnect being the barrier layer.

As a result of the increasing fraction of the total conductor volume (and the cross-sectional area) from the barrier layer, resistivity and electron scattering associated with copper interconnects increases as CD is further reduced, thereby adversely affecting electrical performance. A measure of the electrical performance can be indicated by an RC value (also referred to as RC delay or RC time constant, having units of seconds [s]), where RC is a product of resistance (R) and capacitance (C). While the copper/barrier layer composition can perform optimally down to a cross-sectional conductor area of about 800 nm², as the conductor area decreases further, the RC delay begins to increase to undesirable values, and can cause higher power consumption and reduced circuit performance of the IC, which is undesirable. For these reasons, further technology nodes in the semiconductor industry indicate the replacement of copper interconnects with another conductor.

Various different metals can potentially be used for the BEOL interconnects that may have varying properties, such as different electrochemical potentials than prior used metals or surrounding metals used in BEOL interconnects. The electrochemical potentials of different metals and metal combinations used together in BEOL interconnects may limit the selection of the materials used, such as due to potential corrosion by oxidation/reduction reactions.

For example, ruthenium (Ru) has been identified as a primary candidate for copper replacement and shows improved RC delay than copper at smaller cross-sectional areas, and can be used without a barrier layer in certain implementations. However, ruthenium is also very costly as compared to copper and to other potential metal replacements for copper. Some potential metal replacements for copper are oxidation-prone and tend to corrode by oxidation, such as upon exposure to oxygen (e.g., in the atmosphere) or upon contact with another metal having a larger electrochemical potential, as can occur in BEOL interconnects.

As will be described in further detail, in certain implementations, a hard mask comprising a second metal can be used to pattern interconnect lines formed from a first metal. In certain implementations, the first metal and the second metal can be chosen based on their respective relative electrochemical potentials. Specifically, in certain implementations, when the second metal used for the hard mask has a lower electrochemical potential than the first metal, the second metal can be sputtered onto the sidewalls of the first metal as the interconnect lines are formed by an etching process while the hard mask is in place. In certain implementations, the second metal can coat and seal the sidewalls of the first metal even after the hard mask is removed. In certain implementations, the second metal at the sidewalls of the first metal can be sacrificially oxidized to reduce or eliminate oxidation of the first metal. In certain implementations, various different metal combinations can be selected for the first metal and the second metal in forming the interconnect lines, thereby allowing the use of various oxidation-prone metals for the first metal by protecting the first metal from oxidation in this manner.

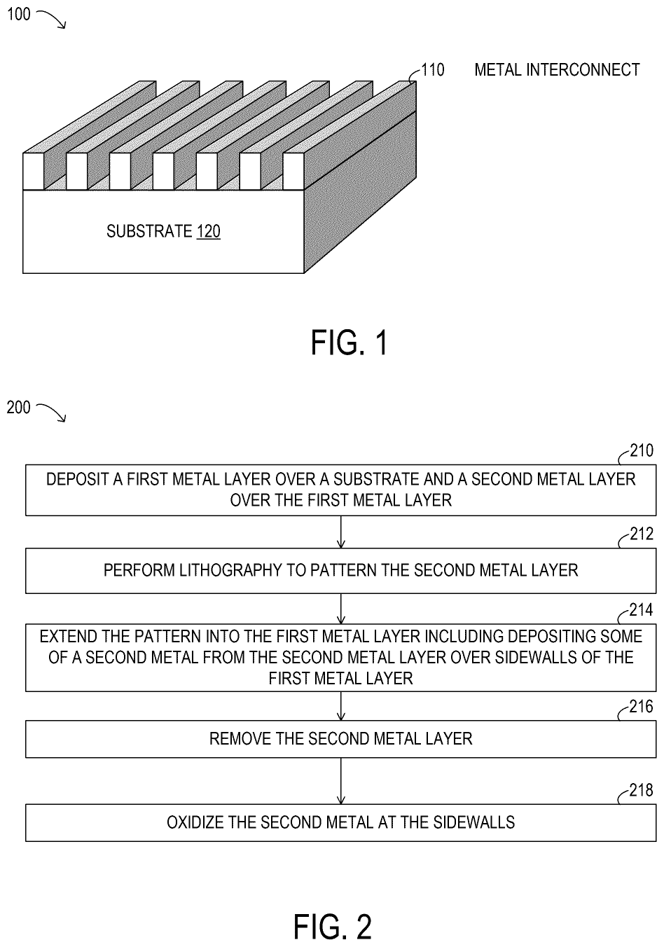

Turning now to the drawings, FIG. 1 is a depiction of patterned metal interconnects 100, in one implementation. FIG. 1 is a schematic illustration that is not necessarily drawn to scale or perspective. As shown in FIG. 1, a substrate 120 can represent various layers in a semiconductor device, such as a dielectric layer formed in a BEOL process. As shown, a metal interconnect 110 is formed from a first metal in the shape of parallel lines having a CD defined by a line width and/or a separation between individual lines. The structure shown in patterned metal interconnects 100 is exemplary for descriptive purposes and can represent various different types of BEOL interconnect structures, in various implementations.

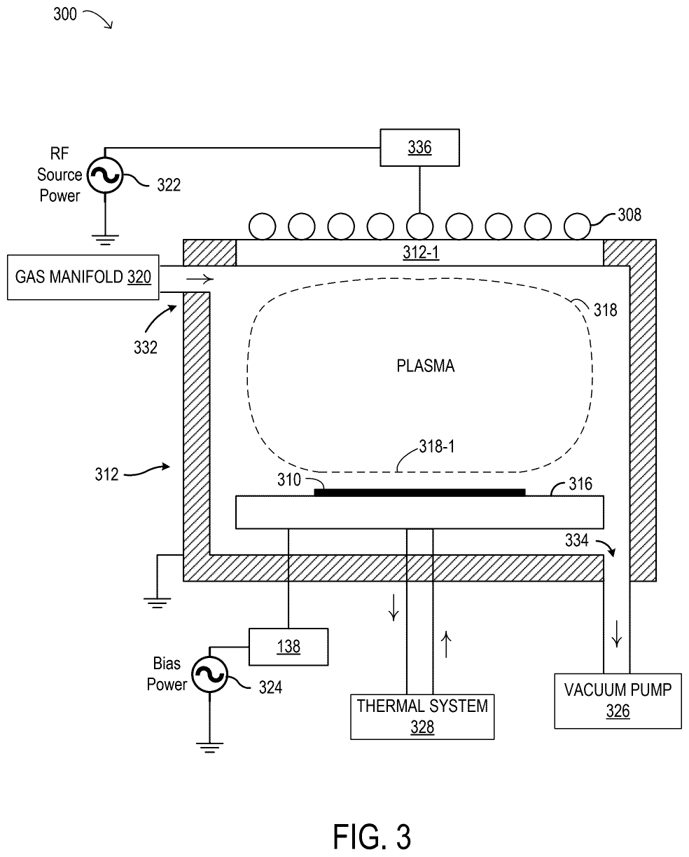

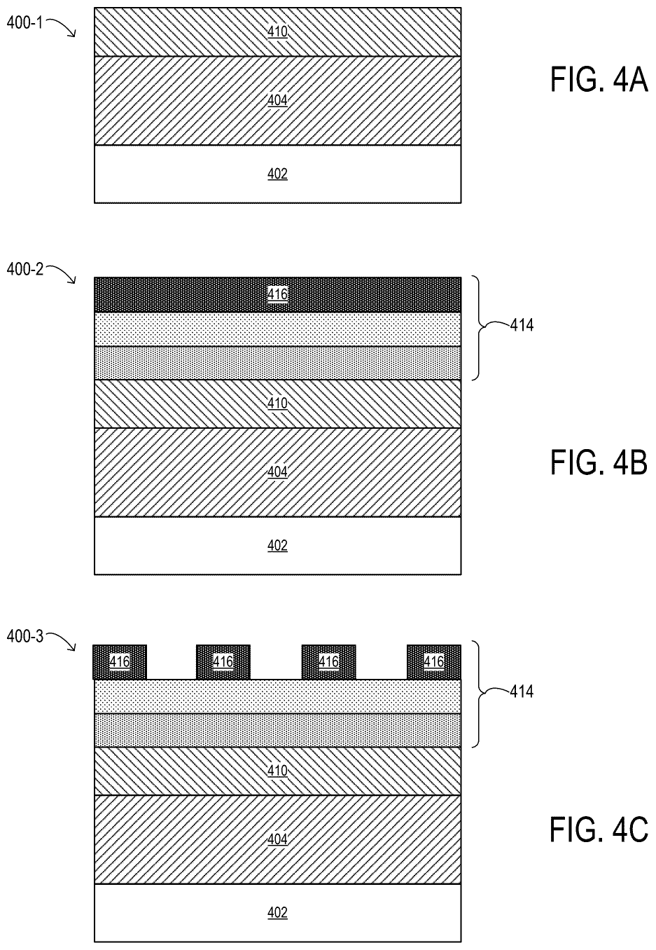

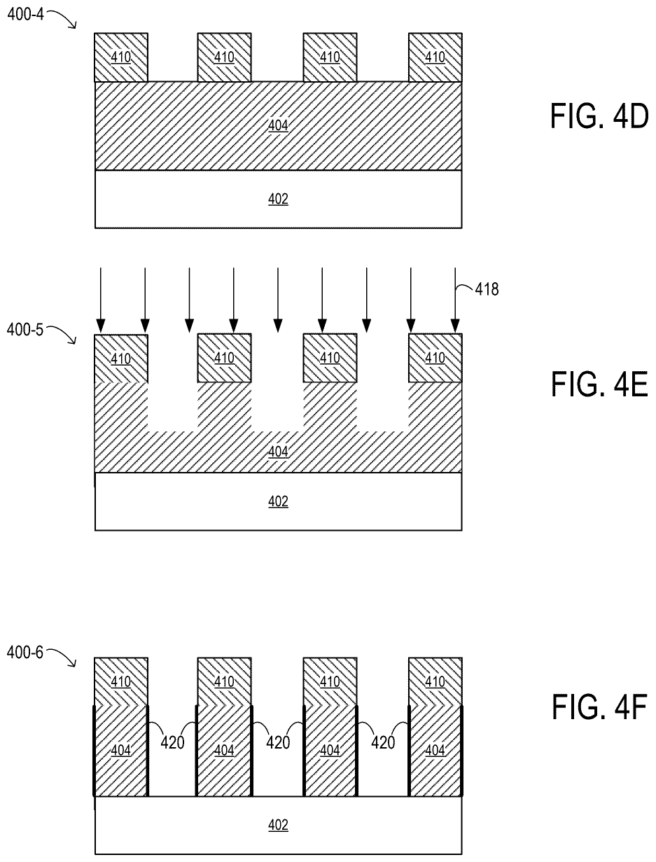

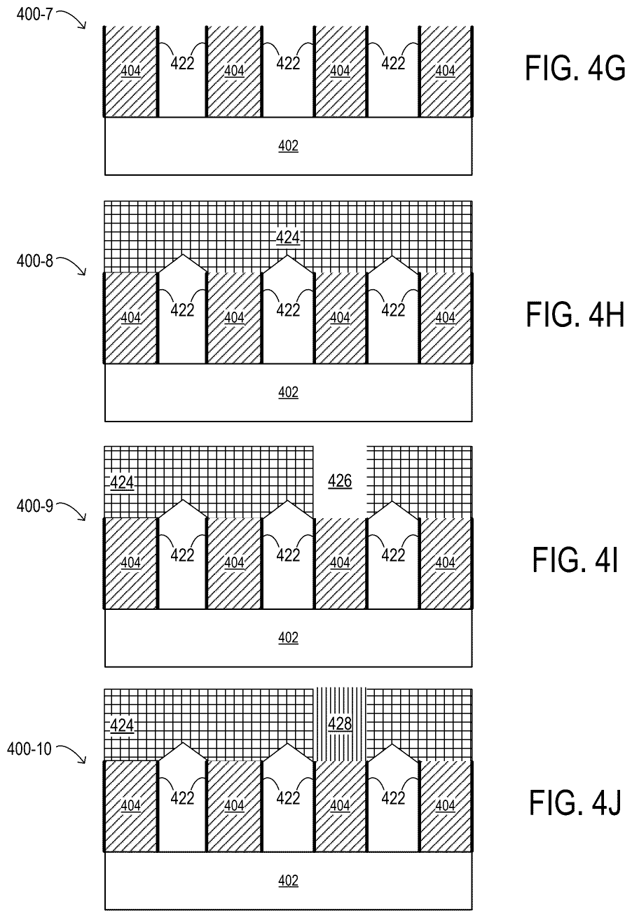

In FIG. 1, as will be described in further detail, metal interconnect 110 can be formed using a lithography patterning process (see also process 400 in FIGS. 4A-4J), and thus, the first metal used for metal interconnect 110 can be a different metal than copper or titanium. Furthermore, metal interconnect 110 can have a thin sputtered coating at the sidewalls (see FIGS. 4F-4J and 8) that is comprised of a second metal that was used as a hard mask (also referred to as a metal mask layer) and that was removed using reactive ion etching (RIE), such as with a plasma processing system 300 described below with respect to FIG. 3. As the metal mask layer was removed using RIE, the second metal was sputtered onto the sidewalls over the first metal forming metal interconnect 110. The second metal was selected to have a lower electrochemical potential than the first metal, and so, the second metal is available for sacrificial oxidation to prevent or limit oxidation of the first metal, which is desirable.

To describe the electrochemistry at a junction of a bimetal cell, such as an electrochemical cell formed by a junction of the first metal and the second metal, the Gibbs free energy ΔGº is given by Equation 1 below.

$$Δ {G}^{∘} = - {nFE}_{cell}^{∘} \qquad Equation 1$$

In Equation 1, n is moles of electrons transferred in the reaction, while F is the charge of 1 mol of electrons (e.g., Faraday constant), and E_{cell} is the electrochemical potential of the electrochemical cell. In Equation 1, when both reactants and products are in their standard states, ΔG is negative for a spontaneous oxidation/reduction reaction. As a result, E_{cell}º will be positive for the spontaneous oxidation/reduction reaction, while a negative value of E_{cell}º will indicate a non-spontaneous reaction that will consume energy, and so, can be stable. For a bimetal junction electrochemical cell, E_{cell}º is given by Equation 2.

$${E}_{cell}^{∘} = {E}_{reduced}^{∘} - {E}_{oxidized}^{∘} \qquad Equation 2$$

In Equation 2, E_{oxidized}º can be a first electrochemical potential of the first metal that is subject to oxidation, while E_{reduced}º can be a second electrochemical potential of the second metal that is subject to reduction. From Equation 2, it can be deduced that as long as E_{reduced}º is less than E_{oxidized}º, then E_{cell}º will be negative (<0), and the electrochemical reaction to oxidize the first metal will not be spontaneous and will have an energy barrier that prevents any oxidation/reduction reaction from proceeding spontaneously. Therefore, for a first metal having E_{oxidized}º as a first electrochemical potential being used for metal interconnect 110, as shown in FIG. 1, a second metal having E_{reduced}º as a second electrochemical potential can be used for the metal mask layer when E_{reduced}º<E_{oxidized}º, in particular implementations. In Table 1 below, various candidate first metals and corresponding second metals are listed that satisfy the relationship E_{reduced}º<E_{oxidized}º, with respect to Equation 2, such that the second metals can be used for the metal mask layer when the first metals are used for metal interconnect 110.

TABLE 1
Various pairs of first metals and second metals.

| FIRST METAL | SECOND METAL |
|---|---|
| Mo | Ti, Ta, Nb, Co, Ni |
| Ru | Mo, Ti, Nb, Ta, W, Cu, Co, Ni |
| Ir | Mo, Ru, Ti, Nb, Ta, SiO₂, W, Cu, Rh, Co, Pd, Ni |
| Pt | Mo, Ru, Ir, Ti, Nb, Ta, SiO₂, W, Cu, Rh, Co, Pd, Ni |
| Nb | Ti |
| Ta | Ti, Nb |
| W | Mo, Ti, Nb, Ta, Co, Ni |
| Cu | Mo, Ti, Nb, Ta, W, Co, Ni |
| Rh | Mo, Ru, TI, Nb, Ta, W, Cu, Co, Ni |
| Co | Ti, Nb, Ta |
| Pd | Mo, Ru, Ti, Nb, Ta, SiO2, W, Cu, Rh, Co, Ni |
| Ni | Ti, Nb, Ta, Co |

It is noted that the element list in Table 1 is not an exhaustive list and that other combinations of the first metal and the second metal can be used in particular implementations. It is also noted that SiO₂, while being a non-metallic compound, can also be used as the hard mask for metal interconnect 110, as indicated in Table 1 and as described in further detail below, and can also be sputtered or coated on the sidewalls of the first metal when the first metal is etched using RIE.

As mentioned above, ruthenium (Ru) is a potential candidate to replace copper in BEOL interconnects, but can be relatively expensive. One particular alternative to ruthenium is molybdenum (Mo) that can be a more economically viable, in some implementations. The use of molybdenum for BEOL interconnects is a potentially viable replacement for copper because molybdenum can be used without necessarily having to be surrounded by a barrier layer, thereby eliminating in situ deposition of the barrier layer, which is desirable. However, one potential disadvantage of replacing copper with molybdenum for BEOL interconnects is that molybdenum is prone to oxidation in atmospheric conditions (e.g., upon exposure to oxygen in the air). Specifically, experimental observations have shown that when metal interconnect 110 is formed using molybdenum as the first metal, and using ruthenium for the metal mask layer as the second metal, the molybdenum interconnect lines will oxidize preferentially, even under relatively short exposure to atmosphere that can occur during normal semiconductor processing, in various implementations. For example, experimental observations have shown that the formation of molybdenum oxides on such molybdenum interconnect lines may not be particularly inhibited during typical BEOL processing steps that can include proscribed cleaning operations. For example, even after short exposure to oxygen or ambient atmosphere, molybdenum oxides can form and consume the molybdenum conductor, which is undesirable for metal interconnects. Therefore, such oxidation of molybdenum for use in forming metal interconnect 110 can be a substantial constraint in the use of molybdenum.

As indicated in Table 1, ruthenium is not among the second metals that can be used for sacrificial oxidation of molybdenum as the first metal, based on their respective electrochemical potentials. For example, experimental observations on planar blanket films has shown that, when molybdenum films are coated with second metals having electrochemical potentials greater than the electrochemical potential of molybdenum, such as ruthenium (Ru), platinum (Pt), or iridium (Ir), the underlying molybdenum fill will still preferentially oxidize, which is undesirable. In contrast, it was also experimentally confirmed that when the planar blanket film of molybdenum were coated with second metals, such as titanium or tantalum, which are listed as second metals for first metal molybdenum in Table 1, then the titanium or tantalum coating will preferentially oxidize, and the underlying molybdenum will remain substantially intact, with little or no oxidation, which is desirable.

Various reduction reactions of different species with corresponding electrochemical potentials are given in Table 2 below, along with respective values of an electrochemical cell in which the respective species is reduced and molybdenum (Mo) is oxidized, as given by Equation 2.

TABLE 2
Various second metals (and SiO₂) paired
with molybdenum (first metal)

| REACTION | E° [V] | E°_{cell} |
|---|---|---|
| Mo³⁺ + 3 e ↔ Mo | −0.200 | 0 |
| Ru²⁺ + 2 e ↔ Ru | 0.455 | 0.655 |
| Ir³⁺ + 3 e ↔ Ir | 1.156 | 1.356 |
| Pt²⁺ + 2 e ↔ Pt | 1.18 | 1.38 |
| Ti²⁺ + 2 e ↔ Ti | −1.630 | −1.430 |
| Nb³⁺ + 3 e ↔ Nb | −1.099 | −0.899 |
| Ta³⁺ + 3 e ↔ Ta | −0.6 | −0.4 |
| SiO₂ (quartz) + 4 H⁺ + 3 e ↔ Si + 2 H₂O | 0.857 | 1.057 |
| W³⁺ + 3 e ↔ W | 0.1 | 0.3 |
| Cu²⁺ + 2 e ↔ Cu | 0.349 | 0.549 |

In Table 2, among the species listed, titanium, niobium, and tantalum will preferentially or sacrificially be oxidized when in contact with molybdenum, which corresponds to Table 1. In Table 3, values for the Gibbs free energy ΔGº in [KJ/mol] for oxides of various metals in Table 2 and SiO₂ are listed.

TABLE 3
Gibbs free energy of selected oxides

| OXIDE | ΔG° |
|---|---|
| RuO₂ | −252.68 |
| MoO₂ | −533.05 |
| WO₃ | −756.7 |
| SiO₂ | −856.3 |
| TiO₂ | −883.27 |
| Nb₂O₅ | −1765.86 |
| Ta₂O₅ | −2088.65 |

As shown in Table 3, oxides of titanium, niobium, and tantalum are thermodynamically more favorable than molybdenum oxide, which is thermodynamically more favorable than ruthenium oxide, for example.

FIG. 2 is a flowchart depicting a method 200 for hard mask protection of metal interconnects, in one implementation. Various operations in method 200 can be rearranged or omitted in different implementations.

In FIG. 2, method 200 can begin at step 210 by depositing a first metal layer over a substrate and a second metal layer over the first metal layer. At step 212, lithography is performed to pattern the second metal layer. At step 214, the pattern is extended into the first metal layer including depositing some of a second metal from the second metal layer over sidewalls of the first metal layer. At step 216, the second metal layer is removed. At step 218, the second metal is oxidized at the sidewalls. For example, metal interconnect 110 in FIG. 1 can be a result of step 216 or step 218 in method 200.

FIG. 3 is a depiction of plasma processing system 300 in one implementation. FIG. 3 is a schematic depiction and is not necessarily drawn to scale or perspective. Plasma processing system 300, as shown, is indicative of various specific implementations and is not limited to any particular design or specific process equipment. Accordingly, in various implementations, plasma processing system 300 may include more or fewer elements than depicted in FIG. 3.

As shown in FIG. 3, plasma processing system 300 includes a process chamber 312 that can be pumped down to a desired vacuum pressure, such as by using a vacuum pump 326 in fluid communication with process chamber 312 via a gas outlet 334. Vacuum pump 326 can be a turbo molecular pump in some implementations, among other types of pumps. Process chamber 312 is configured to load a semiconductor substrate 310 (or simply substrate 310), such as a silicon wafer on which multiple circuit designs in the form of multiple IC die can be fabricated, among other types and materials of substrates. In particular implementations, semiconductor substrate 310 may be 300 mm in diameter, among other sizes. Semiconductor substrate 310 may accordingly be used in process chamber 312 at various stages of fabrication. In particular, semiconductor substrate 310 can represent the various layers and structures described below with respect to FIGS. 4A-4J, while plasma processing system 300 can be used for certain operations, such as reactive ion etching (RIE) described in further detail below with respect to FIGS. 4E and 4F, among other etching operations.

As shown in FIG. 3, semiconductor substrate 310 is supported by a chuck 316 that can retain and secure semiconductor substrate 310 in a desired aligned position with respect to chuck 316. In various implementations, chuck may comprise an electrostatic chuck configured to hold a backside of substrate 310, while a frontside of substrate 310 opposite the backside can be exposed to a plasma 318 inside process chamber 312. Chuck 316 can also be capable of loading and unloading semiconductor substrate 310 from process chamber 312, such as with the cooperation of other equipment, such as handling robots or equipment. Chuck 316 can be mounted within process chamber 312 in a manner that enables raising or lowering of semiconductor substrate 310 with respect to a plasma front 318-1 of plasma 318 generated within process chamber 312. Specifically, after an interior volume of process chamber 312 is pumped down to a sufficient vacuum pressure, such as a sufficiently low vacuum pressure, a gas manifold 320 can meter and deliver a gas mixture in fluid communication with process chamber 312. Gas manifold 320 may include gas canisters, throttle valves, flow meters, pressure sensors, among other components, to maintain a controlled gas flow in process chamber 312. In Table 4 below, various process parameters for plasma processing system 300 that can be modified in various implementations are listed, such as for particular materials to be etched, for particular etch depths, among other specific application criteria.

TABLE 4
Process parameters for plasma processing system 300
Parameter Description

RF source power 322 -- Electrical Power
Bias power 324 - Electrical Pulse Power
Bias power 324 - Electrical Pulse Frequency
Bias power 324 - Electrical Pulse Width
Vacuum pump 326 Pressure
Gas manifold 320
Chuck 316, thermal system 328 Temperature
Etch Duration

In FIG. 3, gas manifold 320 can be configured to mix or provide any number of source gases to process chamber 312 and can further change a composition or a flow rate associated with the gas mixture so provided, for example to independently control a supply of a constituent gas in the gas mixture, at a desired time, such as in response to an instruction from process control equipment that controls plasma processing system 300. An inlet 332 for the gas mixture so provided by gas manifold 320 is shown in fluid communication with process chamber 312. The gas mixture introduced into process chamber 312 is ionized by RF source power 322 to generate a plasma 318 over substrate 310, such as at plasma front 318-1 in proximity to substrate 310. As shown, plasma 318 is a glow discharge, ignited and sustained using electromagnetic (EM) power from a radio frequency (RF) source power 322 coupled to a first electrode 308 that is configured to generate EM fields inside process chamber 312. In some implementations, plasma processing system 300 can be configured in an inductively coupled plasma (ICP) mode, where RF source power 322 is coupled inductively to the gas mixture to generate plasma 318. In some implementations, RF source power 322 can be used in a capacitively coupled plasma (CCP) mode. Accordingly, first electrode 308 is shaped as a planar coil disposed over a top portion of process chamber 312, indicated as a dielectric window 312-1. A first impedance matching circuit 336 in the signal path between RF source power 322 and first electrode 308 can suppress reflections to improve RF power transfer efficiency to plasma 318. As illustrated schematically in FIG. 3, a bias power 324 is coupled, via a second impedance matching circuit 338, to a second electrode, which can be a conductive structure that is located in proximity to chuck 316 and substrate 310. In the configuration shown in plasma processing system 300, first electrode 308 can couple RF source power 322 and the second electrode can couple bias power 324 to plasma 318. In some implementations, bias power 324 supplied to the second electrode may comprise EM power from a pulsed DC source. In plasma processing system 300, the two independent EM power sources (322, 324) coupled to plasma 318 can provide respective independent control over a plasma chemistry (e.g., various radicals and ions created from the gas mixture by RF source power 322) of plasma 318 and a directed kinetic energy of ions to the substrate 310 (e.g., by bias power 324), which controls anisotropy of the plasma etch process. Plasma 318 may accordingly include molecules, free radicals, excited radicals, ions, and electrons.

In plasma processing system 300, an extent to which the gas mixture from gas manifold 320 is excited to plasma 318 can depend on electrical power supplied by RF source power 322 that accordingly can control a gas chemistry of plasma 318 in this manner. As plasma 318 forms, a dark region or sheath surrounds plasma 318 and results in an electric field between plasma 318 and process chamber 312 that serves to contain plasma 318. Plasma 318 may extend towards semiconductor substrate 310 at plasma front 318-1 from which high energy radicals and ions can bombard semiconductor substrate 310. Specifically, a bias power 324 is electrically coupled to process chamber 312 and to semiconductor substrate 310 via chuck 316 (or another electrical connection) to provide an electrical bias to semiconductor substrate 310 for the purpose of regulating an ion energy of the ions bombarding semiconductor substrate 310 from plasma front 318-1, such as to influence a maximum ion bombardment energy during RIE. Because RF source power 322 and bias power 324 can be biased to the same ground potential or reference potential (such as process chamber 312), bias power 324 provides electrical energy to directionally accelerate the ions from plasma front 318-1 in a direction perpendicular to the surface of semiconductor substrate 310, while other radicals and excited species also directionally bombard the surface of semiconductor substrate 310. Furthermore, it is noted that RF source power 322 and bias power 324 can be adjusted independently of each other to provide flexible control of RIE gas chemistry and ion energy, respectively. As noted, a proximity of semiconductor substrate 310 to plasma front 318-1 can also be used for control of RIE, such as by raising or lowering chuck 316. For example, bias power 324 can supply pulsed power, such as at a lower frequency than RF source power 322, to control a kinetic energy of ions at plasma front 318-1, for example to regulate RIE reactions or to favor certain etch reactions or to suppress certain etch reactions. The composition of the etch gas chemistry can vary depending on the materials on semiconductor substrate 310 to be etched. For example, for etching molybdenum, an etch gas chemistry comprising sulfur hexafluoride (SF₆), hexafluoro-cyclobutane (C₄F₆), and argon (Ar) can be used. Other gases that can be used to etch Mo include O₂, Cl₂, HBr, CF₄, or NF₃. In particular implementations, an etch gas comprising a mixture of a halide-containing gas with O₂ and Ar can be used. As a result of the controls and arrangement of elements in plasma processing system 300 shown in FIG. 3, anisotropic plasma etching in the form of RIE using the gas mixture from gas manifold 320 can be performed in process chamber 312 on semiconductor substrate 310, among other types of operations.

Chemical reactions being sensitive to temperature that can increase in substrate 310 during RIE, plasma processing system 300 is equipped with a thermal system 328 configured to maintain substrate 310 at a desired temperature, such as by regulating cooling and/or heating of substrate 310. Accordingly, thermal system 328 may comprise liquid coolant, cooling gas, pumps, heater elements, power supplies, and temperature sensors, among other equipment for regulating cooling and/or heating. In particular implementations, chuck 316 can be mounted on a pedestal having a platen supported by a stem, while thermal system 328 may be configured with conduits or gas flow lines for accessing the platen through the stem of the pedestal on which chuck 316 is mounted, such as in order to circulate a coolant (e.g., He or L N₂) within the pedestal and flow the coolant through grooves in the platen in proximity to the backside of substrate 310. In particular implementations, electrical heating elements may be located within the pedestal proximate the backside of substrate 310 and controlled by electrical power supplied by thermal system 328.

As shown included with plasma processing system 300 in FIG. 3 thermal system 328 can supply a backside of substrate 310 with circulating coolant. A helium (He) coolant can be used to regulate a temperature of semiconductor substrate 310 during RIE, as between about 0 C and 20 C in various implementations, among other ranges. A liquid nitrogen (L N₂) coolant can also be circulated, in addition to or instead of He coolant in different implementations, to provide regulated cryogenic cooling, such as down to about-100C, or a lower temperature, for semiconductor substrate 310, such as when more precise or slower RIE etch rates are desired, among other applications. It is noted that thermal system 328 can include various temperature sensors and instrumentation for measuring temperatures associated with a heating/cooling circulation loop for chuck 316 and semiconductor substrate 310, and can also receive temperature signals and values, such as provided for process chamber 312, in different implementations. Furthermore, during RIE, vacuum pump 326 can evacuate volatile byproducts of the etch process, and can so regulate a desired pressure within process chamber 312. It is noted that other process controls and equipment can be used in different implementations of plasma processing system 300, such as vacuum pumps, temperature controls, heaters, coolers, gas filters, handling equipment, associated process chambers, among other equipment.

FIGS. 4A-4J are depictions of a process 400 for semiconductor fabrication, in one implementation. Various operations in process 400 can be rearranged or omitted in different implementations.

Process 400 may begin with a first process step 400-1 in FIG. 4A depicting deposition of a second metal layer 410 over a first metal layer 404 that is deposited over a substrate 402. Substrate 402 can be similar to substrate 120 in FIG. 1 in particular implementations. Various types of deposition techniques can be used for first process step 400-1, including physical vapor deposition (PVD), chemical vapor deposition (CVD), atomic layer deposition (ALD), among others. At a second process step 400-2 in FIG. 4B, a patterning stack 414 for lithography can be deposited. Patterning stack 414 can include various layers, including a photoresist layer 416. Photoresist layer 416 can be applied as a liquid that is spin coated, among other deposition techniques for patterning stack 414. At a third process step 400-3 in FIG. 4C, lithography is performed to expose and pattern photoresist layer 416, such as to form interconnect lines, as shown in the exemplary implementation of process 400 for descriptive purposes. It is noted that various different types of patterns and openings can be created using lithography in different implementations. At a fourth process step 400-4 in FIG. 4D, etching is performed to remove patterning stack 414 and to extend the pattern of interconnect lines into second metal layer 410. The etching performed for process step 400-4 can be anisotropic RIE, as described above using plasma processing system 300, among other etching techniques. Second metal layer 410, as shown in FIG. 4D can serve as a hard mask (or metal mask layer) for subsequent etching steps to extend the pattern into first metal layer 404.

At a fifth process step 400-5 in FIG. 4E, further etching is performed to extend the pattern formed in FIG. 4D into first metal layer 404. For example, the etching can be anisotropic RIE in which plasma ions and other species are bombarded into the surface of second metal layer 410 in a perpendicular direction represented by arrows 418. In particular, RIE process parameters can be optimized to promote the sputtering of a second metal 420 comprising second metal layer 410 onto sidewalls of first metal layer 404, even as first metal layer 404 is anisotropically etched to extend the pattern into first metal layer 404. At a sixth process step 400-6 in FIG. 4F, deposition of second metal 420 onto sidewalls of the first metal layer are shown as interconnect lines are completed in first metal layer 404, such that substrate 402 is exposed between the interconnect lines. Second metal 420 may be deposited at a thin film having a thickness of a few nanometers or less, such as less than 10 nm, or less than 5 nm, in different implementations. At a seventh process step 400-7 in FIG. 4G, second metal layer 410 is removed. Depending on a composition of second metal 420, various techniques can be used to remove second metal layer 410, such as CMP, wet etching, or a plasma process, among others. As shown in FIG. 4G, second metal 420 has been oxidized to form a metal oxide 422, such as upon exposure to atmosphere that may occur prior to or after removal of second metal layer 410. As noted above, second metal 420 is selected such that metal oxide 422 forms instead of oxidization of first metal layer 404, which is desirable (see also Table 3).

At an eighth process step 400-8 in FIG. 4H, an airgap dielectric 424 is formed over first metal layer 404 and is planarized at a top surface, such as by CMP, among other techniques. At a ninth process step 400-9 in FIG. 4I, a via 426 is formed in dielectric 424, such as by an etch process using plasma processing system 300, among other etching techniques. A single via 426 is shown in process step 400-9 for descriptive clarity, but it is noted that multiple vias can be formed, for example, to form a desired BEOL interconnect structure. At a tenth process step 400-10 in FIG. 4J, via 426 is filled with a third metal 428 to form a conductive pathway to an interconnect line in first metal layer 404. In various implementations, process step 400-10 can be a damascene or dual-damascene process step.

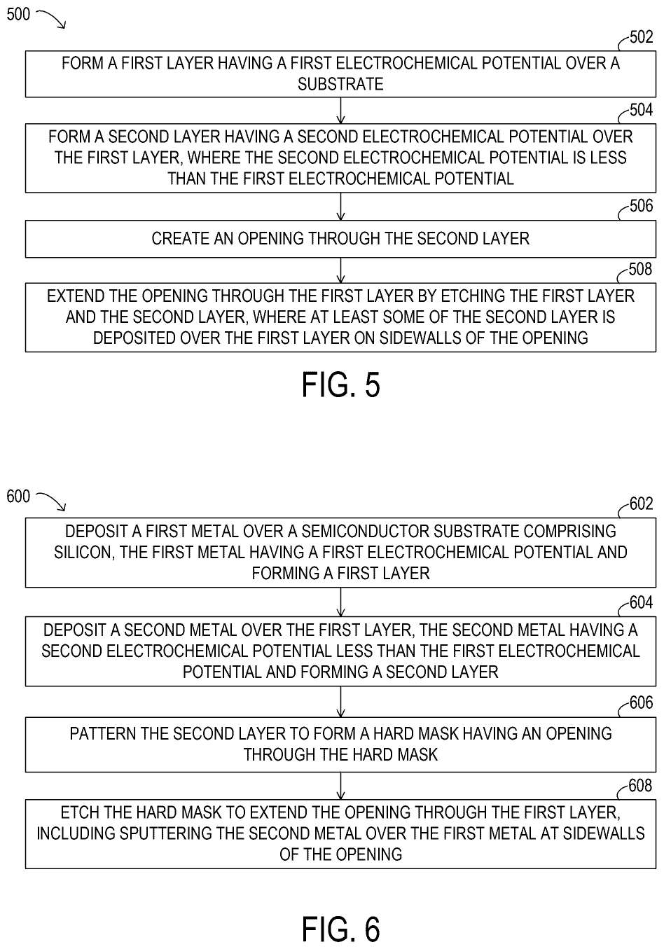

FIG. 5 is a flowchart depicting a method 500 for protecting metal interconnects, in an implementation. Various operations in method 500 can be rearranged or omitted in different implementations.

In FIG. 5, method 500 can begin at step 502 by forming a first layer having a first electrochemical potential on a substrate. At step 504, a second layer having a second electrochemical potential is formed over the first layer, where the second electrochemical potential is less than the first electrochemical potential. At step 506, an opening is created through the second layer. At step 508, the opening is extended through the first layer by etching the first layer and the second layer, where at least some of the second layer is deposited over the first layer on sidewalls of the opening. At step 508, at least some of the second layer can be sputtered over the first layer.

FIG. 6 is a flowchart depicting a method 600 for protecting metal interconnects, in an implementation. Various operations in method 600 can be rearranged or omitted in different implementations.

In FIG. 6, method 600 can begin at step 602 by depositing a first metal over a semiconductor substrate comprising silicon, the first metal having a first electrochemical potential and forming a first layer. At step 604, a second metal is deposited over the first layer, the second metal having a second electrochemical potential less than the first electrochemical potential and forming a second layer. At step 606, the second layer is patterned to form a hard mask having an opening through the hard mask. At step 608, the hard mask is etched to extend the opening through the first layer, including sputtering the second metal over the first metal at sidewalls of the opening.

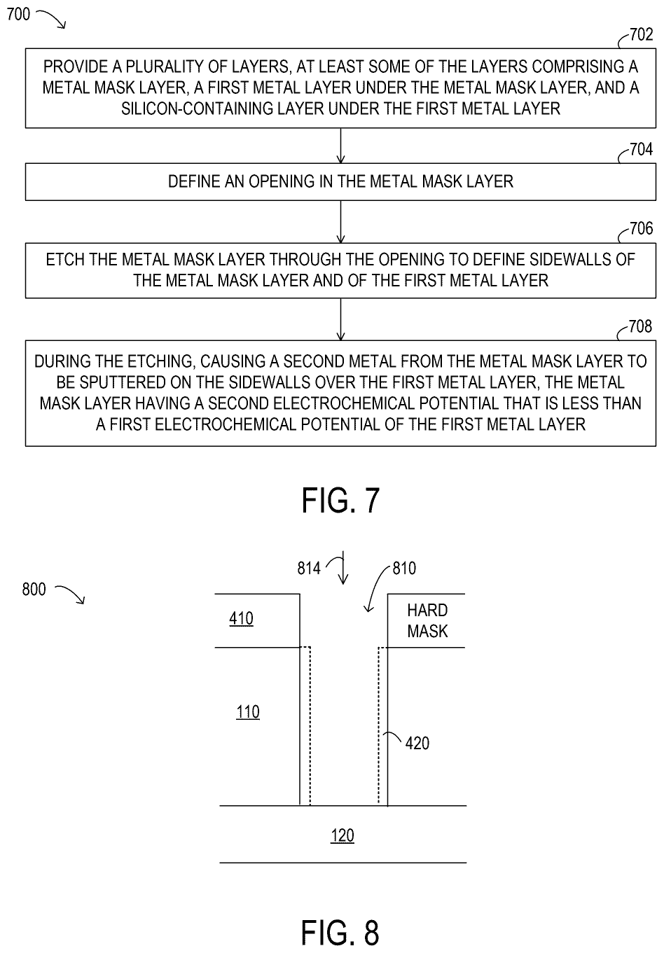

FIG. 7 is a flowchart depicting a method 700 for protecting metal interconnects, in an implementation. Various operations in method 700 can be rearranged or omitted in different implementations.

In FIG. 7, method 700 can begin at step 702 by providing a plurality of layers, at least some of the layers comprising a metal mask layer, a first metal layer under the metal mask layer, and a silicon-containing layer under the first metal layer. At step 704, an opening is defined in the metal mask layer. At step 706, the metal mask layer is etched through the opening to define sidewalls of the metal mask layer and of the first metal layer. During the etching, at step 708, a second metal from the metal mask layer is caused to be sputtered on the sidewalls over the first metal layer, the metal mask layer having a second electrochemical potential that is less than a first electrochemical potential of the first metal layer.

FIG. 8 is a depiction of a sidewall sputtering 800 over an interconnect metal, in one implementation. FIG. 8 shows patterned metal interconnects 100 (see FIG. 1) with a hard mask comprised of second metal layer 410 that is subject to RIE in a direction 814 to extend an opening 810 to form metal interconnect 110. As RIE occurs, second metal 420 (of which second metal layer 410 is comprised) can be deposited on sidewalls of metal interconnect 110. As noted, second metal 420 may be a very thin layer, such as a few nanometers or less, that is preferentially oxidized when exposed to oxygen or ambient air, thereby preserving metal interconnect 110 by preventing oxidation and material removal of metal interconnect 110 to preserve conductivity and electrical performance of metal interconnect 110.

A method for protecting metal interconnects includes forming a first layer having a first electrochemical potential over a substrate, forming a second layer having a second electrochemical potential over the first layer, where the second electrochemical potential is less than the first electrochemical potential The method includes creating an opening through the second layer, and extending the opening through the first layer by etching the first layer and the second layer, where at least some of the second layer is deposited over the first layer on sidewalls of the opening.

Example implementations are described below. Other implementations can also be understood from the entirety of the specification as well as the claims filed herein.

Example 1. A method including: depositing a first layer having a first electrochemical potential over a substrate; depositing a second layer having a second electrochemical potential over the first layer, where the second electrochemical potential is less than the first electrochemical potential; creating an opening through the second layer; and extending the opening through the first layer by etching the first layer and the second layer, where at least some of the second layer is deposited over the first layer on sidewalls of the opening during the extending.

Example 2. The method of example 1, further including: removing the second layer having the opening; exposing the sidewalls to atmosphere to oxidize the second layer deposited on the sidewalls; and depositing a dielectric layer over the first layer to seal the opening.

Example 3. The method of one of examples 1 or 2, further including: forming a via through the dielectric layer to expose the first layer; and filling the via with a conductor that contacts the first layer.

Example 4. The method of one of examples 1 to 3, where the second layer deposited over the first layer on sidewalls of the opening seals the first layer at the sidewalls.

Example 5. The method of one of examples 1 to 4, where etching the first layer and the second layer further includes: etching using reactive ion etching.

Example 6. The method of one of examples 1 to 5, where: the first layer includes Mo, and the second layer includes at least one of: Ti, Ta, Nb, Co, or Ni; the first layer includes Ru, and the second layer includes at least one of: Mo, Ti, Nb, Ta, W, Cu, Co, or Ni; the first layer includes Ir, and the second layer includes at least one of: Mo, Ru, Ti, Nb, Ta, SiO2, W, Cu, Rh, Co, Pd, or Ni; the first layer includes Pt, and the second layer includes at least one of: Mo, Ru, Ir, Ti, Nb, Ta, SiO2, W, Cu, Rh, Co, Pd, or Ni; the first layer includes Nb, and the second layer includes Ti; the first layer includes Ta, the second layer includes at least one of: Ti or Nb; the first layer includes W, and the second layer includes at least one of: Mo, Ti, Nb, Ta, Co, or Ni; the first layer includes Cu, and the second layer includes at least one of: Mo, Ti, Nb, Ta, W, Co, or Ni; the first layer includes Rh, and the second layer includes at least one of: Mo, Ru, Ti, Nb, Ta, W, Cu, Co, or Ni; the first layer includes Co, and the second layer includes at least one of: Ti, Nb, or Ta; the first layer includes Pd, and the second layer includes at least one of: Mo, Ru, Ti, Nb, Ta, SiO2, W, Cu, Rh, Co, or Ni; or the first layer includes Ni, and the second layer includes at least one of: Ti, Nb, Ta, or Co.

Example 7. A process including: depositing a first metal over a semiconductor substrate including silicon, the first metal having a first electrochemical potential and forming a first layer; depositing a second metal over the first layer, the second metal having a second electrochemical potential less than the first electrochemical potential and forming a second layer; patterning the second layer to form a hard mask having an opening through the hard mask; and etching the hard mask to extend the opening through the first layer, and, during the etching, sputtering the second metal over the first metal at sidewalls of the opening.

Example 8. The process of example 7, further including: removing the second layer to expose the first layer; oxidizing the second metal deposited on the sidewalls; and sealing the opening by depositing a dielectric layer over the first layer.

Example 9. The process of one of examples 7 or 8, further including: forming a via through the dielectric layer to expose the first metal; and filling the via with a third metal that contacts the first metal.

Example 10. The process of one of examples 7 to 9, where depositing the dielectric layer further includes: depositing the dielectric layer as an airgap dielectric.

Example 11. The process of one of examples 7 to 10, where sputtering the second metal over the first metal at sidewalls of the opening further includes: sealing the first layer from a surrounding environment at the sidewalls.

Example 12. The process of one of examples 7 to 11, where etching the hard mask further includes: etching using reactive ion etching.

Example 13. The process of one of examples 7 to 12, where: the first layer includes Mo, and the second layer includes at least one of: Ti, Ta, Nb, Co, or Ni; the first layer includes Ru, and the second layer includes at least one of: Mo, Ti, Nb, Ta, W, Cu, Co, or Ni; the first layer includes Ir, and the second layer includes at least one of: Mo, Ru, Ti, Nb, Ta, W, Cu, Rh, Co, Pd, or Ni; the first layer includes Pt, and the second layer includes at least one of: Mo, Ru, Ir, Ti, Nb, Ta, W, Cu, Rh, Co, Pd, or Ni; the first layer includes Nb, and the second layer includes Ti; the first layer includes Ta, and the second layer includes at least one of: Ti or Nb; the first layer includes W, and the second layer includes at least one of: Mo, Ti, Nb, Ta, Co, or Ni; the first layer includes Cu, and the second layer includes at least one of: Mo, Ti, Nb, Ta, W, Co, or Ni; the first layer includes Rh, and the second layer includes at least one of: Mo, Ru, Ti, Nb, Ta, W, Cu, Co, or Ni; the first layer includes Co, and the second layer includes at least one of: Ti, Nb, or Ta; the first layer includes Pd, and the second layer includes at least one of: Mo, Ru, Ti, Nb, Ta, W, Cu, Rh, Co, or Ni; or the first layer includes Ni, and the second layer includes at least one of: Ti, Nb, Ta, or Co.

Example 14. A process including: providing a plurality of layers, at least some of the layers including a metal mask layer, a first metal layer under the metal mask layer, and a silicon-containing layer under the first metal layer; defining an opening in the metal mask layer; etching the metal mask layer through the opening to define sidewalls of the metal mask layer and of the first metal layer; and during the etching, causing a second metal from the metal mask layer to be sputtered on the sidewalls over the first metal layer, the metal mask layer having a second electrochemical potential that is less than a first electrochemical potential of the first metal layer.

Example 15. The process of example 14, further including: removing the metal mask layer to expose the first metal layer; oxidizing the second metal deposited on the sidewalls by exposing the first metal layer to oxygen; and sealing the opening by forming a dielectric layer over the first metal layer.

Example 16. The process of one of examples 14 or 15, further including: etching a via through the dielectric layer to expose the first metal layer; and filling the via with a third metal that contacts the first metal layer.

Example 17. The process of one of examples 14 to 16, where forming the dielectric layer further includes: depositing the dielectric layer as an airgap dielectric.

Example 18. The process of one of examples 14 to 17, where causing the second metal from the metal mask layer to be sputtered on the sidewalls over the first metal layer further includes: sealing the first metal layer from the environment at the sidewalls.

Example 19. The process of one of examples 14 to 18, where etching the metal mask layer further includes: etching using reactive ion etching.

Example 20. The process of one of examples 14 to 19, where: the first metal layer includes Mo, the second metal includes at least one of: Ti, Ta, Nb, Co, or Ni; the first metal layer includes Ru, and the second metal includes at least one of: Mo, Ti, Nb, Ta, W, Cu, Co, or Ni; the first metal layer includes Ir, and the second metal includes at least one of: Mo, Ru, Ti, Nb, Ta, W, Cu, Rh, Co, Pd, or Ni; the first metal layer includes Pt, and the second metal includes at least one of: Mo, Ru, Ir, Ti, Nb, Ta, W, Cu, Rh, Co, Pd, or Ni; the first metal layer includes Nb, and the second metal includes Ti; the first metal layer includes Ta, and the second metal includes at least one of: Ti or Nb; the first metal layer includes W, and the second metal includes at least one of: Mo, Ti, Nb, Ta, Co, or Ni; the first metal layer includes Cu, and the second metal includes at least one of: Mo, Ti, Nb, Ta, W, Co, or Ni; the first metal layer includes Rh, and the second metal includes at least one of: Mo, Ru, Ti, Nb, Ta, W, Cu, Co, or Ni; the first metal layer includes Co, and the second metal includes at least one of: Ti, Nb, or Ta; the first metal layer includes Pd, and the second metal includes at least one of: Mo, Ru, Ti, Nb, Ta, W, Cu, Rh, Co, or Ni; or the first metal layer includes Ni, and the second metal includes at least one of: Ti, Nb, Ta, or Co.

While this disclosure has been described with reference to illustrative implementations, this description is not intended to be construed in a limiting sense. Various modifications and combinations of the illustrative implementations, as well as other implementations, will be apparent to persons skilled in the art upon reference to the description. It is therefore intended that the appended claims encompass any such modifications or implementations.

1. A method comprising:
depositing a first layer having a first electrochemical potential over a substrate;
depositing a second layer having a second electrochemical potential over the first layer, wherein the second electrochemical potential is less than the first electrochemical potential;
creating an opening through the second layer; and
extending the opening through the first layer by etching the first layer and the second layer, wherein at least some of the second layer is deposited over the first layer on sidewalls of the opening during the extending.

2. The method of claim 1, further comprising:
removing the second layer having the opening;
exposing the sidewalls to atmosphere to oxidize the second layer deposited on the sidewalls; and
depositing a dielectric layer over the first layer to seal the opening.

3. The method of claim 2, further comprising:
forming a via through the dielectric layer to expose the first layer; and
filling the via with a conductor that contacts the first layer.

4. The method of claim 1, wherein the second layer deposited over the first layer on sidewalls of the opening seals the first layer at the sidewalls.

5. The method of claim 1, wherein etching the first layer and the second layer further comprises:
etching using reactive ion etching.

6. The method of claim 1, wherein:
the first layer comprises Mo, and the second layer comprises at least one of: Ti, Ta, Nb, Co, or Ni;
the first layer comprises Ru, and the second layer comprises at least one of: Mo, Ti, Nb, Ta, W, Cu, Co, or Ni;
the first layer comprises Ir, and the second layer comprises at least one of: Mo, Ru, Ti, Nb, Ta, SiO₂, W, Cu, Rh, Co, Pd, or Ni;
the first layer comprises Pt, and the second layer comprises at least one of: Mo, Ru, Ir, Ti, Nb, Ta, SiO₂, W, Cu, Rh, Co, Pd, or Ni;
the first layer comprises Nb, and the second layer comprises Ti;
the first layer comprises Ta, and the second layer comprises at least one of: Ti or Nb;
the first layer comprises W, and the second layer comprises at least one of: Mo, Ti, Nb, Ta, Co, or Ni;
the first layer comprises Cu, and the second layer comprises at least one of: Mo, Ti, Nb, Ta, W, Co, or Ni;
the first layer comprises Rh, and the second layer comprises at least one of: Mo, Ru, Ti, Nb, Ta, W, Cu, Co, or Ni;
the first layer comprises Co, and the second layer comprises at least one of: Ti, Nb, or Ta;
the first layer comprises Pd, and the second layer comprises at least one of: Mo, Ru, Ti, Nb, Ta, SiO₂, W, Cu, Rh, Co, or Ni; or
the first layer comprises Ni, and the second layer comprises at least one of: Ti, Nb, Ta, or Co.

7. A process comprising:
depositing a first metal over a semiconductor substrate comprising silicon, the first metal having a first electrochemical potential and forming a first layer;
depositing a second metal over the first layer, the second metal having a second electrochemical potential less than the first electrochemical potential and forming a second layer;
patterning the second layer to form a hard mask having an opening through the hard mask; and
etching the hard mask to extend the opening through the first layer, and, during the etching, sputtering the second metal over the first metal at sidewalls of the opening.

8. The process of claim 7, further comprising:
removing the second layer to expose the first layer;
oxidizing the second metal deposited on the sidewalls; and
sealing the opening by depositing a dielectric layer over the first layer.

9. The process of claim 8, further comprising:
forming a via through the dielectric layer to expose the first metal; and
filling the via with a third metal that contacts the first metal.

10. The process of claim 8, wherein depositing the dielectric layer further comprises:
depositing the dielectric layer as an airgap dielectric.

11. The process of claim 7, wherein sputtering the second metal over the first metal at sidewalls of the opening further comprises:
sealing the first layer from a surrounding environment at the sidewalls.

12. The process of claim 7, wherein etching the hard mask further comprises:
etching using reactive ion etching.

13. The process of claim 7, wherein:
the first layer comprises Mo, and the second layer comprises at least one of: Ti, Ta, Nb, Co, or Ni;
the first layer comprises Ru, and the second layer comprises at least one of: Mo, Ti, Nb, Ta, W, Cu, Co, or Ni;
the first layer comprises Ir, and the second layer comprises at least one of: Mo, Ru, Ti, Nb, Ta, W, Cu, Rh, Co, Pd, or Ni;
the first layer comprises Pt, and the second layer comprises at least one of: Mo, Ru, Ir, Ti, Nb, Ta, W, Cu, Rh, Co, Pd, or Ni;
the first layer comprises Nb, and the second layer comprises Ti;
the first layer comprises Ta, and the second layer comprises at least one of: Ti or Nb;
the first layer comprises W, and the second layer comprises at least one of: Mo, Ti, Nb, Ta, Co, or Ni;
the first layer comprises Cu, and the second layer comprises at least one of: Mo, Ti, Nb, Ta, W, Co, or Ni;
the first layer comprises Rh, and the second layer comprises at least one of: Mo, Ru, Ti, Nb, Ta, W, Cu, Co, or Ni;
the first layer comprises Co, and the second layer comprises at least one of: Ti, Nb, or Ta;
the first layer comprises Pd, and the second layer comprises at least one of: Mo, Ru, Ti, Nb, Ta, W, Cu, Rh, Co, or Ni; or
the first layer comprises Ni, and the second layer comprises at least one of: Ti, Nb, Ta, or Co.

14. A process comprising:
providing a plurality of layers, at least some of the layers comprising a metal mask layer, a first metal layer under the metal mask layer, and a silicon-containing layer under the first metal layer;
defining an opening in the metal mask layer;
etching the metal mask layer through the opening to define sidewalls of the metal mask layer and of the first metal layer; and
during the etching, causing a second metal from the metal mask layer to be sputtered on the sidewalls over the first metal layer, the metal mask layer having a second electrochemical potential that is less than a first electrochemical potential of the first metal layer.

15. The process of claim 14, further comprising:
removing the metal mask layer to expose the first metal layer;
oxidizing the second metal deposited on the sidewalls by exposing the first metal layer to oxygen; and
sealing the opening by forming a dielectric layer over the first metal layer.

16. The process of claim 15, further comprising:
etching a via through the dielectric layer to expose the first metal layer; and
filling the via with a third metal that contacts the first metal layer.

17. The process of claim 15, wherein forming the dielectric layer further comprises:
depositing the dielectric layer as an airgap dielectric.

18. The process of claim 14, wherein causing the second metal from the metal mask layer to be sputtered on the sidewalls over the first metal layer further comprises:
sealing the first metal layer from the environment at the sidewalls.

19. The process of claim 14, wherein etching the metal mask layer further comprises:
etching using reactive ion etching.

20. The process of claim 14, wherein:
the first metal layer comprises Mo, and the second metal comprises at least one of: Ti, Ta, Nb, Co, or Ni;
the first metal layer comprises Ru, and the second metal comprises at least one of: Mo, Ti, Nb, Ta, W, Cu, Co, or Ni;
the first metal layer comprises Ir, and the second metal comprises at least one of: Mo, Ru, Ti, Nb, Ta, W, Cu, Rh, Co, Pd, or Ni;
the first metal layer comprises Pt, and the second metal comprises at least one of: Mo, Ru, Ir, Ti, Nb, Ta, W, Cu, Rh, Co, Pd, or Ni;
the first metal layer comprises Nb, and the second metal comprises Ti;
the first metal layer comprises Ta, and the second metal comprises at least one of: Ti or Nb;
the first metal layer comprises W, and the second metal comprises at least one of: Mo, Ti, Nb, Ta, Co, or Ni;
the first metal layer comprises Cu, and the second metal comprises at least one of: Mo, Ti, Nb, Ta, W, Co, or Ni;
the first metal layer comprises Rh, and the second metal comprises at least one of: Mo, Ru, Ti, Nb, Ta, W, Cu, Co, or Ni;
the first metal layer comprises Co, and the second metal comprises at least one of: Ti, Nb, or Ta;
the first metal layer comprises Pd, and the second metal comprises at least one of: Mo, Ru, Ti, Nb, Ta, W, Cu, Rh, Co, or Ni; or
the first metal layer comprises Ni, and the second metal comprises at least one of: Ti, Nb, Ta, or Co.
